(19) United States
(12) Patent Application Publication
(10) Pub. No.: US 2009/0065931 A1
(43) Pub. Date: Mar. 12, 2009

(54) PACKAGED INTEGRATED CIRCUIT AND METHOD OF FORMING THEREOF

(75) Inventors: Sudarshan V. Rangaraj, Chandler, AZ (US); Sanka Ganesan, Chandler, AZ (US); Dongming He, Chandler, AZ (US); Richard J. Harries, Chandler, AZ (US); Sairam Agraharam, Phoenix, AZ (US)

Correspondence Address: GROSSMAN, TUCKER, PERREAULT & PFLEGER, PLLC;C/O Intellevate, LLC, P. O. BOX 52050, MINNEAPOLIS, MN, 55402, US

(73) Assignee: INTEL CORPORATION, Santa Clara, CA (US)

(21) Appl. No.: 11/853,461

(22) Filed: Sep. 11, 2007

(51) Int. Cl. H01L 23/52; H01L 21/44

(52) U.S. Cl. 257/737; 438/614; 257/E23.141; 257/E21.476

(57) ABSTRACT

Disclosed is a packaged integrated circuit and a method of forming thereof. The packaged integrated circuit includes a substrate, a plurality of solder bumps, a semiconductor die and a plurality of copper bumps. The plurality of solder bumps are configured on the substrate. Each of the plurality of solder bumps has a height of about 40 micrometers (μm) to about 65 μm. Further, the plurality of copper bumps are configured on the semiconductor die. Each of the plurality of copper bumps has a height of about 10 μm to about 25 μm. The semiconductor die is disposed above the substrate such that the plurality of copper bumps are coupled to the plurality of solder bumps, which in turn, couples the semiconductor die to the substrate.

### FIELD OF THE DISCLOSURE

The present disclosure generally relates to packaged Integrated Circuits (ICs) and, more particularly, to first level interconnects using copper bumps and solder bumps between semiconductor dies and substrates.

### BRIEF DESCRIPTION OF THE DRAWINGS

The advantages and features of the present disclosure will become better understood with reference to the following detailed description and claims taken in conjunction with the accompanying drawings, wherein like elements are identified with like symbols, and in which:

FIG. 1 is a diagram illustrating a prior-art packaged integrated circuit;

FIG. 2A is a diagram illustrating a packaged integrated circuit, according to an exemplary embodiment of the present disclosure; and

FIG. 2B is a diagram illustrating a packaged integrated circuit, according to another exemplary embodiment of the present disclosure.

Like reference numerals refer to like parts throughout the description of several views of the drawings.

### DETAILED DESCRIPTION OF THE DISCLOSURE

For a thorough understanding of the present disclosure, reference is to be made to the following detailed description, including the appended claims, in connection with the above-described drawings. Although the present disclosure is described in connection with exemplary embodiments, the disclosure is not intended to be limited to the specific forms set forth herein. It is understood that various omissions and substitutions of equivalents are contemplated as circumstances may suggest or render expedient, but these are intended to cover the application or implementation without departing from the spirit or scope of the claims of the present disclosure. Also, it is to be understood that the phraseology and terminology used herein is for the purpose of description and should not be regarded as limiting.

The terms “a” and “an” herein do not denote a limitation of quantity, but rather denote the presence of at least one of the referenced item.

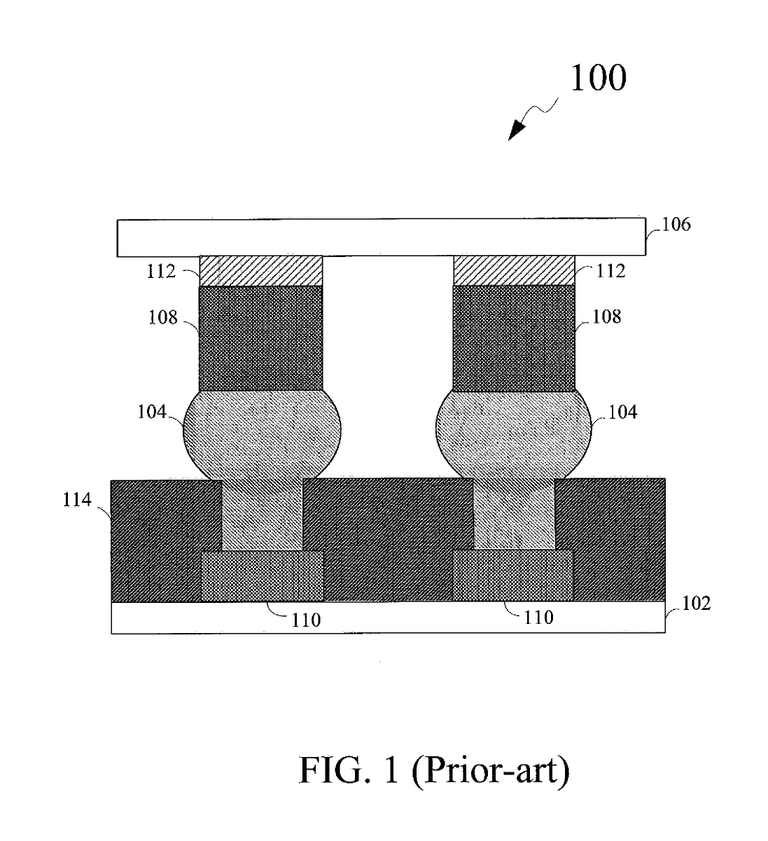

FIG. 1 is a schematic diagram illustrating a prior-art packaged integrated circuit 100 (hereinafter referred to as ‘circuit 100’). The circuit 100 comprises a substrate 102, a plurality of solder bumps 104, a semiconductor die 106 and a plurality of copper bumps 108. The substrate 102 acts as a package or a die carrier for the semiconductor die 106. The substrate 102 comprises a plurality of substrate pads 110 formed thereon. The solder bumps 104 may be disposed on the substrate pads 110. In a typical circuit, the solder bumps 104 may be configured on the substrate pads 110 of the substrate 102 using a micro-ball technology. A solder mask layer 114 may be deposited around the substrate pads 110 of the substrate 102 to control the shape of the solder bumps 104

The semiconductor die 106 is disposed above the substrate 102. The semiconductor die 106 may include at least one semiconductor device. The copper bumps 108 are configured on the semiconductor die 106. In a typical circuit 100, the copper bumps 108 may be disposed on a plurality of bonding pads 112 formed on the semiconductor die 106 as shown in FIG. 1. In a typical circuit 100, the copper bumps 108 are formed on the plurality of bonding pads 112 of the semiconductor die 106 by an electroplating process.

The solder bumps 104 and copper bumps 108 may be connected by a reflow soldering process. The connection of the solder bumps 104 and the copper bumps forms a first level interconnect (FLI) joints, which connects the semiconductor die 106 to the substrate 102. In a typical assembled circuit 100, height of a solder bump 104 generally lies between about 10 micrometers (μm) to about 20 μm and height of a copper bump 108 is generally about 47 μm. Due to large height of the copper bumps 108, which is about 47 μm, the semiconductor die 106 may experience a large stress. Also due to the small heights of solder bumps 104, the solder bumps 104 have a tendency to undergo large strain during thermal excursions, which can increase the possibilities of rupture of the FLI joints.

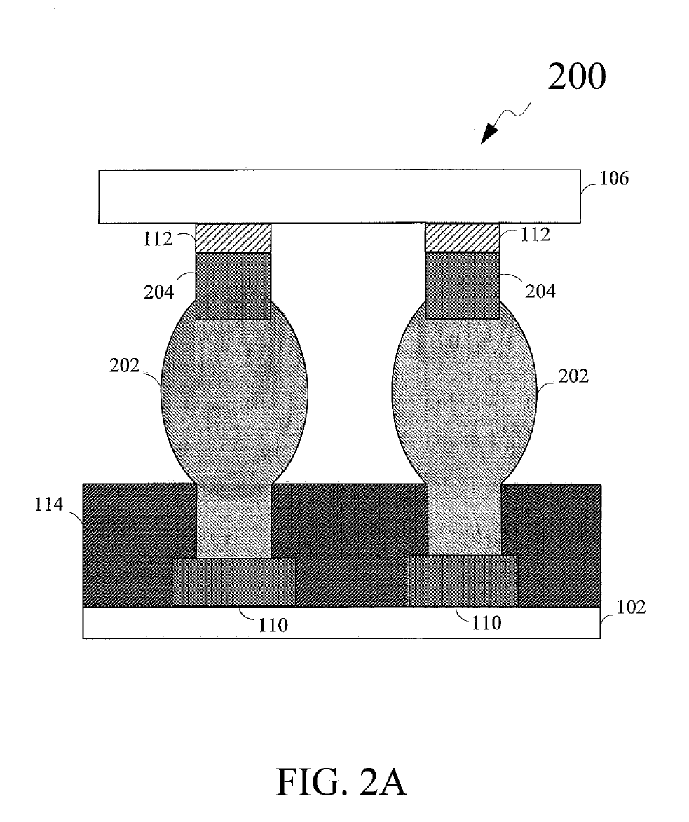

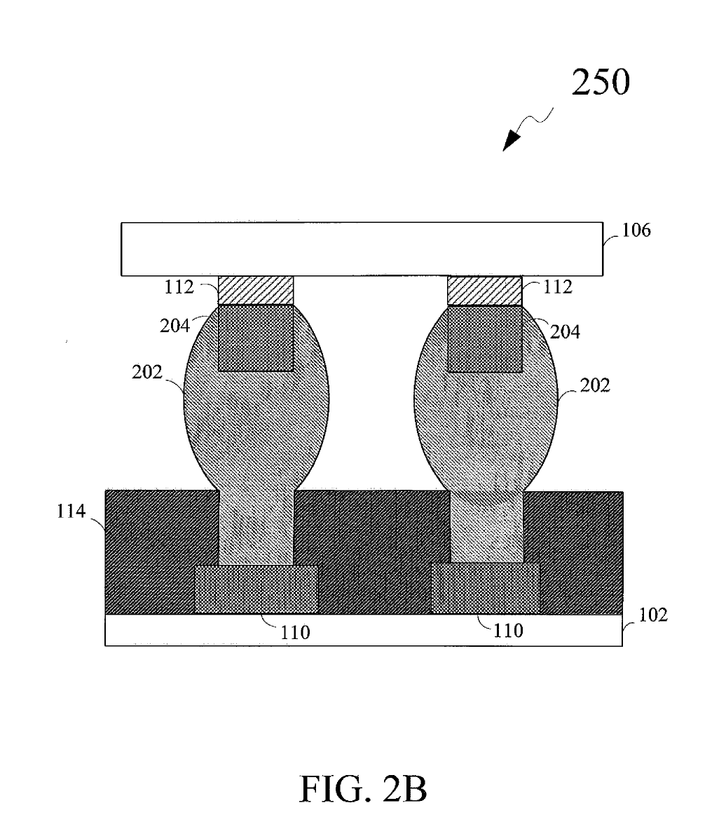

Referring now to FIG. 2A, a diagram illustrating a packaged integrated circuit 200 (hereinafter referred to as ‘circuit 200’) is shown, according to an exemplary embodiment of the present disclosure. The circuit 200 comprises the substrate 102, a plurality of solder bumps 202, the semiconductor die 106 and a plurality of copper bumps 204. The substrate 102 acts as a package or package carrier. The solder bumps 202 are configured on the substrate 102. More specifically, the substrate 102 comprises the plurality of solder pads 110 formed thereon, on which the solder bumps 202 are disposed using a technology including but not limited to as mentioned in conjunction with FIG. 1. For example, the solder bumps 202 may be configured on the substrate pads 110 of the substrate 102 using micro-ball technology. In one embodiment of the present disclosure, each of the solder bumps 202 (before semiconductor assembly to the substrate) has a height of about 40 μm to about 65 μm. Such an increase in height may be achieved by increasing the diameter of micro-balls used in the micro-ball technology by about 10 percent to about 30 percent as compared to micro-balls used in the formation of the solder bumps 104 (See FIG. 1). Accordingly, by increasing the diameter of the micro-balls, the height of the each of the solder bumps 202 (after assembly of the semiconductor die to the substrate) may be increased to about 20 μm to about 50 μm as compared to the range of about 10 μm to about 20 μm as in case of the solder bumps 104 (See FIG. 1).

The semiconductor die 106 is disposed above the substrate 102. The semiconductor die 106 may include at least one semiconductor device. The copper bumps 204 are configured on the semiconductor die 106. More specifically, the semiconductor die 106 comprises the plurality of bonding pads 112 formed thereon, on which the copper bumps 204 are disposed by using a technology including but not limited to as mentioned in conjunction with FIG. 1. For example, the copper bumps 204 may be disposed on the bonding pads 112 of the semiconductor die 106 by an electroplating process used thereon, as in case of the copper bumps 108 discussed in conjunction with FIG. 1. In one embodiment of the present disclosure, each of the copper bumps 204 has a height of about 10 μm to about 25 μm. Such a decrease in height of the copper bumps 204 (as compared to that of solder bumps 104) may be achieved by shortening electroplating time. For instance, the height of each of the copper bumps 204 may be decreased to about 10 μm to about 25 μm as compared to that of 47 μm in case of the copper bumps 108 (See FIG. 1).

In this configuration of the semiconductor die 106 disposed above the substrate 102, the solder bumps 202 are coupled to the copper bumps 204, which in turn, couple the semiconductor die 106 to the substrate 102. The solder bumps 202 and the copper bumps 204 may be coupled by the reflow soldering process as mentioned in conjunction with FIG. 1. The connection of the solder bumps 202 and the copper bumps 204 forms the FLI joints, which connects the semiconductor die 106 to the substrate 102. The FLI joints may take various shapes due to wetting characteristics of the solder material in the solder bumps 202 on copper in the copper bumps 204. In this embodiment of the present disclosure, as shown in FIG. 2A, the FLI joints are of shapes where the copper bumps 204 are partially immersed within the solder bumps 202.

In another exemplary embodiment of the present disclosure, as shown in a packaged integrated circuit 250 in FIG. 2B, the shape of the FLI joints is such that the copper bumps 204 are completely immersed within the solder bumps 202. However, the packaged integrated circuit 250 is similar in terms of the components to the circuit 200.

The present disclosure further provides a method for forming a packaged integrated circuit. The method comprises providing a substrate and configuring a plurality of solder bumps on the substrate. The configuration of the solder bumps on the substrate comprises forming a plurality of solder pads on the substrate and disposing the solder bumps on the bonding pads. Optionally, a solder mask layer may be formed around area of the plurality of solder pads on the substrate. The solder bumps are configured using a micro-ball technology to impart a height of about 40 μm to about 65 μm to each of the solder bumps (before the assembly of semiconductor die to the substrate).

The method further comprises providing a semiconductor die and configuring a plurality of copper bumps on the semiconductor die. The configuration of the copper bumps on the semiconductor die comprises forming a plurality of bonding pads on the semiconductor die and disposing the copper bumps on the bonding pads. The copper bumps are configured using an electroplating process to impart a height of about 10 μm to about 25 μm to each of the copper bumps. Thereafter, the method comprises disposing the semiconductor die above the substrate, such that, the solder bumps are coupled to the copper bumps. A reflow soldering process may be used to couple the solder bumps to the copper bumps. In an embodiment of the present disclosure, coupling the solder bumps and the copper bumps may comprise immersing the copper bumps partially within the solder bumps. In another embodiment of the present disclosure, the coupling the solder bumps and the copper bumps may comprise immersing the copper bumps completely within the solder bumps.

Various embodiments of the present disclosure provide following advantages. Due to the use of a smaller height of copper bumps 204 in the range of about 10 μm to about 25 μm, the stress in the semiconductor die 106 may be reduced substantially. Further, the use of a height of the solder bumps 202 in the range of about 20 μm to about 40 μm (after coupling the semiconductor die to the substrate) may provide reduction in the strain in the solder bumps 202. The use of such solder bumps 202 may allow a reduced required percentage of Gold (Au) content in solder material. The reduced percentage of Au in the solder material may minimize the degradation in the solder compliance and ductility due to the possible dissolution of Au from a substrate surface. The present disclosure also provides an increase in the volume of the solder bumps 202, which provides an improved integrated circuit assembly in terms of solder bump collapse. Such a feature may further mitigate some of the open FLI joints issues encountered during a die and a substrate assembly.

The foregoing descriptions of specific embodiments of the present disclosure have been presented for purposes of illustration and description. They are not intended to be exhaustive or to limit the disclosure to the precise forms disclosed, and obviously many modifications and variations are possible in light of the above teaching. The embodiments were chosen and described in order to best explain the principles of the disclosure and its practical application, to thereby enable others skilled in the art to best utilize the disclosure and various embodiments with various modifications as are suited to the particular use contemplated. It is understood that various omission and substitutions of equivalents are contemplated as circumstance may suggest or render expedient, but such are intended to cover the application or implementation without departing from the spirit or scope of the claims of the present disclosure.

What is claimed is:

1. A packaged integrated circuit, comprising:
a substrate;
a plurality of solder bumps configured on the substrate, each of the plurality of solder bumps having a height of about 40 micrometers (μm) to about 65 μm;
a semiconductor die; and
a plurality of copper bumps configured on the semiconductor die, each of the plurality of copper bumps having a height of about 10 μm to about 25 μm;
wherein the semiconductor die is disposed above the substrate and the plurality of solder bumps are coupled to the plurality of copper bumps.

2. The packaged integrated circuit of claim 1, wherein the plurality of solder bumps are disposed on a plurality of solder pads formed on the substrate.

3. The packaged integrated circuit of claim 1, wherein the plurality of copper bumps are disposed on a plurality of bonding pads formed on the semiconductor die.

4. The packaged integrated circuit of claim 1, wherein the plurality of copper bumps are coupled to the plurality of solder bumps, such that the plurality of copper bumps are partially immersed within the plurality of solder bumps.

5. The packaged integrated circuit of claim 1, wherein the plurality of copper bumps are coupled to the plurality of solder bumps, such that the plurality of copper bumps are completely immersed within the plurality of solder bumps.

6. A method for forming a packaged integrated circuit, the method comprising:
providing a substrate;
configuring a plurality of solder bumps on the substrate, each of the plurality of solder bumps having a height of about 40 micrometers (μm) to about 65 μm;
providing a semiconductor die;
configuring a plurality of copper bumps on the semiconductor die, each of the plurality of copper bumps having a height of about 10 μm to about 25 μm;
disposing the semiconductor die above the substrate; and
coupling the plurality of solder bumps to the plurality of copper bumps.

7. The method of claim 6, wherein configuring the plurality of solder bumps on the substrate comprises:
forming a plurality of solder pads on the substrate; and
disposing the plurality of solder bumps on the plurality of solder pads.

8. The method of claim 6, wherein configuring the plurality of copper bumps on the semiconductor die comprises:
forming a plurality of bonding pads on the semiconductor die; and
disposing the plurality of copper bumps on the plurality of bonding pads.

9. The method of claim 6, wherein coupling the plurality of solder bumps to the plurality of copper bumps comprises partially immersing the plurality of copper bumps within the plurality of solder bumps.

10. The method of claim 6, wherein coupling the plurality of solder bumps to the plurality of copper bumps comprises completely immersing the plurality of copper bumps within the plurality of solder bumps.
